(19) United States
(12) Patent Application Publication
(10) Pub. No.: US 2012/0256197 A1
(43) Pub. Date: Oct. 11, 2012

(54) ORGANIC ELECTROLUMINESCENCE ELEMENT

(75) Inventors: Yuko Matsuhisa, Osaka (JP); Norihiro Ito, Osaka (JP); Hiroya Tsuji, Kyoto (JP); Nobuhiro Ide, Osaka (JP)

(73) Assignee: PANASONIC CORPORATION, Osaka (JP)

(21) Appl. No.: 13/515,313

(22) PCT Filed: Dec. 16, 2010
(86) PCT No.: PCT/JP2010/072660

§ 371 Date: Jun. 12, 2012

(30) Foreign Application Priority Data
Dec. 16, 2009 (JP) 2009-285483

(51) Int. Cl. H01L 33/02

(52) U.S. Cl. 257/79; 257/E33.045

(57) ABSTRACT

The organic electroluminescence device includes an anode, a cathode, a first electron injection layer, an electron transport layer, and a light emitting layer. The first electron injection layer is made of alkali metal and is formed between the anode and the cathode. The electron transport layer is formed between the first electron injection layer and the anode. The light emitting layer is formed between the electron transport layer and the anode. The organic electroluminescence element further includes a second electron injection layer. The second electron injection layer is formed between the first electron injection layer and the electron transport layer. The second electron injection layer is made of amorphous inorganic material.

### TECHNICAL FIELD

The present invention relates to an organic electroluminescence element available for equipment such as a light source for lighting, a backlight device for liquid crystal displays, and a flat-panel display.

### BACKGROUND ART

Some of organic light emitting devices are referred to as organic electroluminescence elements. For example, such an organic light emitting device has a laminated structure including a transparent electrode serving as an anode, a hole transport layer, a light emitting layer (an organic light emitting layer), an electron injection layer, and an electrode serving as a cathode, which are stacked in this order and provided on one side of a transparent substrate. With regard to the organic electroluminescence element with such a laminated structure, a voltage applied between the anode and the cathode causes recombination of electrons injected into the light emitting layer from the light emitting layer and holes injected into the light emitting layer from the hole transport layer, within the light emitting layer, and then light is generated. Light generated at the light emitting layer is emitted outside via the transparent electrode and the transparent substrate.

The organic electroluminescence element is designed to give a self-emission light in various wavelengths, with a relatively high yield. Such organic electroluminescence elements are expected to be applied for production of displaying apparatuses (e.g., light emitters used for such as flat panel displays), and light sources (e.g., liquid-crystal displaying backlights and illuminating light sources). Some of organic electroluminescence elements have already been developed for practical uses.

A basic laminated structure of the organic electroluminescence element is an anode/light emitting layer/cathode structure. In addition, there have been proposed various laminated structures, such as, an anode/hole transport layer/light emitting layer/electron transport layer/cathode structure, an anode/hole injection layer/hole transport layer/light emitting layer/electron transport layer/cathode structure, an anode/hole injection layer/light emitting layer/electron transport layer/electron injection layer/cathode structure, and, an anode/hole injection layer/light emitting layer/electron injection layer/cathode structure.

Various organizations study optimization of thicknesses and materials of layers of the laminated structure for the purpose of improving the light emitting efficiency and lowering the driving voltage of the organic electroluminescence element. A result of such research revealed that a low electron injection performance from the cathode to the light emitting layer causes a decrease in the light-emitting efficiency and an increase in the driving voltage of the organic electroluminescence element. In brief, it is known that improvement of the electron injection performance to the light emitting layer is effective for increasing the light emitting efficiency and lowering the driving voltage.

For example, there has been proposed an organic electroluminescence element which includes a layer containing an alkali metal with a relatively low work function as an electron injection layer in contact with the cathode (see JP 3529543 B, and JP 3694653 B). This organic electroluminescence element shows an improved electron injection performance.

However, the electron injection performance of the organic electroluminescence element including the layer containing an alkali metal as the electron injection layer in contact with the cathode as disclosed in JP 3529543 B and JP 3694653 B is not enough. Therefore, a further increase in the light emitting efficiency and a further decrease in the driving voltage are coveted.

Additionally, with regard to the organic electroluminescence element having a layer containing an alkali metal as the electron injection layer in contact with the cathode, it is known that alkali metals adopted as an electron injection material are likely to be diffused toward the light emitting layer and such diffusion causes a decrease in the light emitting efficiency (see Miyamoto, Takashi., Ishibashi, Kiyoshi., “(special topic) display (2) analysis techniques of organic EL”, Toray Research Center, THE TRC NEWS, No. 98, 14-18, (Jan, 2007)).

### DISCLOSURE OF INVENTION

In view of the above insufficiency, the present invention has been aimed to propose an organic electroluminescence element with an improved light emitting efficiency and a lowered driving voltage.

The organic electroluminescence element in accordance with the present invention includes an anode, a cathode, a first electron injection layer, an electron transport layer, and a light emitting layer. The first electron injection layer is made of an alkali metal and is formed between the anode and the cathode. The electron transport layer is formed between the first electron injection layer and the anode. The light emitting layer is formed between the electron transport layer and the anode. The organic electroluminescence element further includes a second electron injection layer. The second electron injection layer is formed between the first electron injection layer and the electron transport layer. The second electron injection layer is made of an amorphous inorganic material.

Preferably, the amorphous inorganic material is an electrically insulating inorganic material, and the second electron injection layer has an average thickness in a range of 0.3 nm to 30 nm.

More preferably, the second electron injection layer has an average thickness in a range of 0.3 nm to 10 nm.

In a preferred aspect, the amorphous inorganic material is an electrically insulating inorganic material with a specific electric resistance equal to or more than 1×10⁵ Ωcm.

In an alternative preferred aspect, the amorphous inorganic material is an electrically conducting inorganic material with a specific electric resistance less than 1×10⁵ Ωcm.

In a preferred aspect, the alkali metal is lithium, and the amorphous inorganic material is IZO.

In a preferred aspect, the alkali metal is cesium, and the amorphous inorganic material is LiF.

In a preferred aspect, the alkali metal is lithium, and the amorphous inorganic material is aluminum.

In a preferred aspect, the alkali metal is rubidium, and the amorphous inorganic material is molybdenum oxide.

In a preferred aspect, the alkali metal is lithium, and the amorphous inorganic material is magnesium.

### BRIEF DESCRIPTION OF DRAWINGS

FIG. 1 is a schematic cross-sectional view illustrating the organic electroluminescence element of the present embodiment,

FIG. 2 is a schematic cross-sectional view illustrating the alternative configuration of the organic electroluminescence element of the present embodiment, and

FIG. 3 is a depth profile diagram of Li based on the analysis performed after the respective organic electroluminescence elements of an example and a comparative example were driven.

### BEST MODE FOR CARRYING OUT THE INVENTION

The organic electroluminescence element of the present embodiment includes, between an anode 1 and a cathode 2, a first electron injection layer 5a, a second electron injection layer 5b, an electron transport layer 4, and a light emitting layer 3 which are arranged in this order from cathode 2, as shown in FIG. 1.

In the organic electroluminescence element of the present embodiment, anode 1 is stacked over a first surface of a substrate 6. Cathode 2 faces the opposite surface of anode 1 from substrate 6. With regard to the organic electroluminescence element of the present embodiment, substrate 6 is constituted by a transparent substrate (translucent substrate), and anode 1 is constituted by a transparent electrode, and cathode 2 is constituted by an electrode configured to reflect light emitted from light emitting layer 3, and a second surface of substrate 6 is adopted as a light projection surface.

Besides, in an instance shown in FIG. 1, light emitting layer 3 is formed on anode 1. Like a general organic electroluminescence element, a hole injection layer and/or a hole transport layer may be interposed between anode 1 and light emitting layer 3, if necessary.

Substrate 6 is constituted by a transparent substrate. This transparent substrate is not limited to a non-colored transparent substrate but may be a subtly colored transparent substrate. The transparent substrate constituting substrate 6 may be a glass substrate such as a soda lime glass substrate and a non-alkali glass substrate. The transparent substrate is not limited to such a glass substrate, may be a plastic film (or plastic substrate) made of a resin (e.g., a polyester resin, a polyolefin resin, a polyamide resin, an epoxy resin and a fluorine resin). The glass substrate may be formed of a frosted glass. Further, substrate 6 may contain particles (powders, bubbles or the like) having refractive indexes different from that of substrate 6, for causing light diffusion effects. When the element is not configured to radiate light through substrate 6, substrate 6 is not required to be formed of a light transmissive material but may be formed of other material in consideration of a light emission performance and a durability of the element and the like. In particular, substrate 6 may be a substrate (e.g., a metal substrate, an enameled substrate, and an AlN substrate) made of a highly thermal conductive material for reducing heat generation arising from electricity passing through the element. In this instance, it is possible to promote heat dissipation, and therefore the organic electroluminescence element can emit light with a high brightness and show prolonged life time.

Anode 1 is designed to inject holes into light emitting layer 3. Preferably, anode 1 is made of an electrode material selected from a metal, an alloy, an electrically conductive compound, and a mixture thereof which have a large work function. Preferably, the electrode material is selected to have a work function in a range of 4 eV to 6 eV in order to limit a difference between an energy level of anode 1 and an HOMO (Highest Occupied Molecular Orbital) level within an appropriate range. For example, the electrode material of such an anode 1 may be an electrically conductive light transmissive material selected from CuI, ITO, SnO₂, ZnO, IZO, or the like. The electrically conductive light transmissive material may be selected from an electrically conductive polymer (e.g., PEDOT and polyaniline), an electrically conductive polymer prepared by doping a polymer with acceptors, and a carbon nanotube. For example, anode 1 is formed as a thin film on the first surface of substrate 6 by means of a vacuum vapor deposition method, a sputtering method, and an application. When a conductive transparent substrate (e.g., an ITO substrate) is served as anode 1, it is possible to omit substrate 6.

When the element is configured such that the light emitted from light emitting layer 3 is directed outwards through anode 1, anode 1 is preferably formed to have a light transmission of 70% or more. In addition, anode 1 is preferably formed to have a sheet resistance of several hundreds Ω/sq or less, more preferably 100 Ω/sq or less. Anode 1 can be controlled to have a suitable thickness depending on selected material for achieving its light transmission and its sheet resistance mentioned above, and is preferably formed to have a thickness of 500 nm or less, more preferably in a range of 10 to 200 nm.

Cathode 2 is designed to inject electrons into light emitting layer 3. Preferably, cathode 2 is made of an electrode material selected from a metal, an alloy, an electrically conductive compound, and a mixture thereof which have a small work function. Preferably, the electrode material is selected to have a work function in a range of 1.9 eV to 5 eV in order to limit a difference between an energy level of cathode 1 and an LUMO (Lowest Unoccupied Molecular Orbital) level within an appropriate range. For example, the electrode material of such a cathode 2 may be selected from aluminum, silver, magnesium, and an alloy including at least one of these metals (e.g., magnesium-silver mixture, magnesium-indium mixture, and aluminum-lithium alloy). Cathode 2 may be a laminated film including an ultra-thin film made of Al₂O₃ and a thin film made of Al. The ultra-thin film may be made of a metal, a metal oxide, and a mixture thereof. The ultra-thin film is defined as a thin film with a thickness of 1 nm or less which transmits electrons through a tunnel injection process. Cathode 2 may be formed of a transparent electrode such as ITO and IZO, for passing light therethrough.

Cathode 2 can be prepared as a thin film by use of a vacuum vapor deposition method or a sputtering method. When the element is configured such that the light emitted from light emitting layer 3 is propagated outward through anode 1, cathode 2 is preferably formed to have a light transmission of 10% or less. Alternatively, when cathode 2 is served as a transparent electrode for propagating therethrough the light emitted from light emitting layer 3 (or for propagating the light emitted from light emitting layer 3, through both of anode 1 and cathode 2), cathode 2 is preferably formed to have a light transmission of 70% or more. In this instance, cathode 2 is suitably controlled depending on selected materials to have a desirable light transmission performance, and preferably controlled to have a thickness of 500 nm or less, more preferably in a range of 100 to 200 nm.

Light emitting layer 3 can be formed of any of well-known materials for fabrication of an electroluminescence element, such as anthracene, naphthalene, pyrene, tetracene, coronene, perylene, phthaloperylene, naphthaloperylene, diphenylbutadiene, tetraphenylbutadiene, coumalin, oxadiazole, bisbenzoxazoline, bisstyryl, cyclopentadiene, a quinoline-metal complex, a tris(8-hydroxyquinolinate)aluminum complex, a tris(4-methyl-8-quinolinate)aluminum complex, a tris(5-phenyl-8-quinolinate)aluminum complex, an aminoquinoline-metal complex, a benzoquinoline-metal complex, a tri-(p-terphenyl-4-yl)amine, 1-aryl-2,5-di(2-thienyl)pyrrole derivative, pyrane, quinacridone, rubrene, a distyrylbenzene derivative, a distyrylarylene derivative, a distyrylamine derivative, or various phosphor pigments as well as the above-listed materials and their derivatives. Light emitting layer 3 is not required to be formed of the above substance. Light emitting layer 3 is preferably formed of a mixture of luminescent materials selected among these substances. Light emitting layer 3 may be formed of one of other luminescent materials causing photoemission from spin-multiplets, such as phosphorescent materials and compounds having phosphorescent moieties, instead of fluorescent compounds listed above. Light emitting layer 3 made of the above material can be formed by a dry-type process (e.g., vapor deposition and transferring) or a wet-type process (e.g., spin-coating, spray-coating, diecoating and gravure printing).

The aforementioned hole injection layer may be formed of a hole injection organic material, a hole injection metal oxide, an acceptor-type organic (or inorganic) material, a p-doped layer, or the like. The hole injection organic material is selected to exhibit a hole-transporting performance and have a work function in a range of about 5.0 eV to 6.0 eV as well as a strong adhesion to anode 1. For example, the hole injection organic material may be CuPc, a starburst amine or the like. The hole injection metal oxide may be an oxide of a metal which is selected from molybdenum (Mo), rhenium (Re), tungsten (W), vanadium (V), zinc (Zn), indium (In), tin (Sn), gallium (Ga), titanium (Ti) and aluminum (Al). The hole injection metal oxide is not required to be only one metal oxide, but may be a combination of oxides of plural metals including at least one of the metals listed above. For example, the hole injection metal oxide may be a combination of oxides of indium and tin, a combination of oxides of indium and zinc, a combination of oxides of aluminum and gallium, a combination of oxides of gallium and zinc, and a combination of oxides of titanium and niobium. The hole injection layer made of the above material can be formed by a dry-type process (e.g., vapor deposition and transferring) or a wet-type process (e.g., spin-coating, spray-coating, diecoating and gravure printing).

The hole transport layer may be formed of one selected among compounds exhibiting hole transporting performances. For example, the hole transport layer may be formed of an arylamine compound such as 4,4′-bis[N-(naphthyl)-N-phenyl-amino]biphenyl (alpha-NPD), N,N′-bis(3-methylphenyl)-(1,1′-biphenyl)-4,4′-diamine (TPD), 2-TNATA, 4,4′,4″-tris(N-(3-methylphenyl)N-phenylamino)triphenylamine (MTDATA), 4,4′-N,N′-dicarbazolebiphenyl (CBP), Spiro-NPD, spiro-TPD, spiro-TAD, and TNB. Instead, the hole transport layer may be formed of an amine compound containing a carbazole group, an amine compound containing fluorene derivative. Instead, conventional hole transport materials can be employed to form the hole transport layer.

The electron transport material layer may be formed of one selected among compounds exhibiting electron-transporting performances. Such an electron-transporting compound may be one selected among metal complexes (e.g., Alq₃) exhibiting electron-transporting performances, and heterocyclic compounds such as phenanthroline derivatives, pyridine derivatives, tetrazine derivatives, oxadiazole derivatives. Instead, another conventional electron-transporting material can be employed as the electron transport material.

First electron injection layer 5a and second electron injection layer 5b as mentioned in the above is served as a layer for facilitating injection of electrons from cathode 2 to light emitting layer 3.

The material of first electron injection layer 5a is limited to an alkali metal such as lithium, sodium, potassium, rubidium, and cesium.

Second electron injection layer 5b can be made of an electrically insulating inorganic material. The electrically insulating inorganic material is not limited to particular one but is required to have a specific electric resistance equal to or more than 1×10⁵ Ωcm. For example, the electrically insulating inorganic material may be one selected from metal halides such as metal fluorides (e.g., lithium fluoride and magnesium fluoride) and metal chlorides (e.g., sodium chloride and magnesium chloride). Instead, the electrically insulating inorganic material may be one selected from oxides, nitrides, carbides, and oxynitrides of metal such as aluminum (Al), cobalt (Co), zirconium (Zr), titanium (Ti), vanadium (V), niobium (NB), chromium (Cr), tantalum (Ta), tungsten (W), manganese (Mn), molybdenum (Mo), ruthenium (Ru), iron (Fe), nickel (Ni), copper (Cu), gallium (Ga), and zinc (Zn). For example, the electrically insulating inorganic material may be an insulator (e.g., Al₂O₃, MgO, iron oxide, AlN, SiN, SiC, SiON, and BN), a silicon compound (e.g., SiO₂ and SiO), and a carbon compound. Each of these substances can be deposited to form a thin film by use of a vacuum vapor deposition, a spattering, or the like.

When second electron injection layer 5b is made of the electrically insulating inorganic material, second electron injection layer 5b is preferably formed to have a deposition thickness in a range of 0.3 nm to 30 nm, more preferably equal to or less than 10 nm. When second electron injection layer 5b is formed to have a deposition thickness of 10 nm or less, it is possible to reduce an electric resistance of second electron injection layer 5b to a negligible level, and therefore a driving voltage can be lowered. For example, in a situation where second electron injection layer 5b is deposited by use of a deposition device, the deposition thickness of second electron injection layer 5b is measured by use of a crystal oscillator, and is defined as an average thickness. In brief, when the deposition thickness is small (e.g., 0.5 nm or less), second electron injection layer 5b may exhibit an islands structure rather than a continuous structure. However, second electron injection layer 5b is not necessarily formed to have a continuous structure.

Second electron injection layer 5b is not necessarily made of an electrically insulating inorganic material but may be made of an electrically conducting inorganic material. The electrically conducting inorganic material is not limited to particular one but is required to have a specific electric resistance less than 1×10⁵ Ωcm. For example, the electrically conducting inorganic material may be one selected from metals and electrically conducting compounds. The electrically conducting inorganic material may be one selected from metals such as aluminum (Al), cobalt (Co), zirconium (Zr), titanium (Ti), vanadium (V), niobium (NB), chromium (Cr), tantalum (Ta), tungsten (W), manganese (Mn), molybdenum (Mo), ruthenium (Ru), iron (Fe), nickel (Ni), copper (Cu), gallium (Ga), and zinc (Zn). Instead, the electrically conducting inorganic material may be one selected from ITO, SnO₂, ZnO, IZO, and the like.

When second electron injection layer 5b is made of the electrically conducting inorganic material, second electron injection layer 5b is preferably formed to have a deposition thickness in a range of 0.3 nm to 50 nm. As long as the electric resistance of second electron injection layer 5b does not cause deterioration of a light emission performance of the organic electroluminescence element, second electron injection layer 5b may have a thickness greater than 50 nm.

Regardless of that second electron injection layer 5b is made of either the electrically insulating inorganic material or the electrically conducting inorganic material, it is important that second electron injection layer 5b is made of an amorphous inorganic material. Second electron injection layer 5b may be formed by means of depositing the electrically insulating inorganic material or the electrically conducting inorganic material under a condition where an amorphous thin film (not limited to a film having a continuous structure) is formed. In addition to the substances listed above, second electron injection layer 5b may be made of an amorphous metal such as amorphous Si and amorphous Ge.

According to the organic electroluminescence element of the present embodiment as explained in the above, at least light emitting layer 3, electron transport layer 4, second electron injection layer 5b, and first electron injection layer 5a are formed between anode 1 and cathode 2, and are arranged in this order from anode 1 to cathode 2. First electron injection layer 5a adjacent to cathode 2 is made of an alkali metal, and second electron injection layer 5b adjacent to anode 1 is made of an amorphous inorganic material.

In other words, the organic electroluminescence element of the present embodiment includes anode 1, cathode 2, first electron injection layer 5a, electron transport layer 4, and light emitting layer 3. First electron injection layer 5a is made of an alkali metal and is formed between anode 1 and cathode 2. Electron transport layer 4 is formed between first electron injection layer 5a and anode 1. Light emitting layer 3 is formed between electron transport layer 4 and anode 1. The organic electroluminescence element of the present embodiment further includes second electron injection layer 5b. Second electron injection layer 5b is formed between first electron injection layer 5a and electron transport layer 4. Second electron injection layer 5b is made of an amorphous inorganic material.

The organic electroluminescence element of the present embodiment as described in the above can have the improved electron injection performance and suppress diffusion of alkali metal particles from first electron injection layer 5a toward anode 1 (light emitting layer 3, in the instance shown in FIG. 1). Consequently, it is enabled to improve the light emitting efficiency, and lower the driving voltage. Further, according to the organic electroluminescence element of the present embodiment, since second electron injection layer 5b is made of an amorphous inorganic material, second electron injection layer 5b can be formed by use of a vapor deposition technique. Thus, it is possible to facilitate the fabrication of the organic electroluminescence element and lower the production cost thereof. In the organic electroluminescence element of the present embodiment, as mentioned in the above, second electron injection layer 5b is made of the amorphous inorganic material. Therefore, in contrast to a comparative example where second electron injection layer 5b is made of a crystalline inorganic material, the deposition process of second electron injection layer 5b can be facilitated. The film which is formed as second electron injection layer 5b shows isotropic electric conductivity. Therefore, it is possible to suppress inhomogeneous distribution of the electric conductivity on the surface of second electron injection layer 5b, and therefore unevenness of light emission can be suppressed. Further, second electron injection layer 5b shows relatively low film (membrane) stress. Consequently, second electron injection layer 5b strongly adheres to first electron injection layer 5a and electron transport layer 4 and is hardly separated from first electron injection layer 5b and electron transport layer 4. Thus, long-term reliability can be improved. Further, the driving voltage can be lowered.

When an electrically insulating inorganic material is adopted as the amorphous inorganic material of second electron injection layer 5b, and when second electron injection layer 5b is designed to have an average thickness in a range of 0.3 nm to 30 nm, it is possible to prevent an increase in the driving voltage which would otherwise occur due to the electrical resistance of second electron injection layer 5b.

Other configurations may be employed to form the organic electroluminescence element in accordance with the present invention, unless extending beyond technical objects of the present invention. The configuration of the present embodiment is not limited to the laminated structure shown in FIG. 1. For example, as mentioned in the above, a hole injection layer and/or a hole transport layer may be added if necessary. Alternatively, the organic electroluminescence element includes a plurality of light emitting layers 3 between anode 1 and cathode 2. For example, the plurality of light emitting layers 3 may include a blue light emitting layer with hole transport properties, a green light emitting layer with hole transport properties, and a red light emitting layer with hole transport properties, or may include a blue light emitting layer with electron transport properties, a green light emitting layer with electron transport properties, and a red light emitting layer with electron transport properties. The organic electroluminescence element may include a structure constituted by stacking the plural laminated structure other than substrate 6.

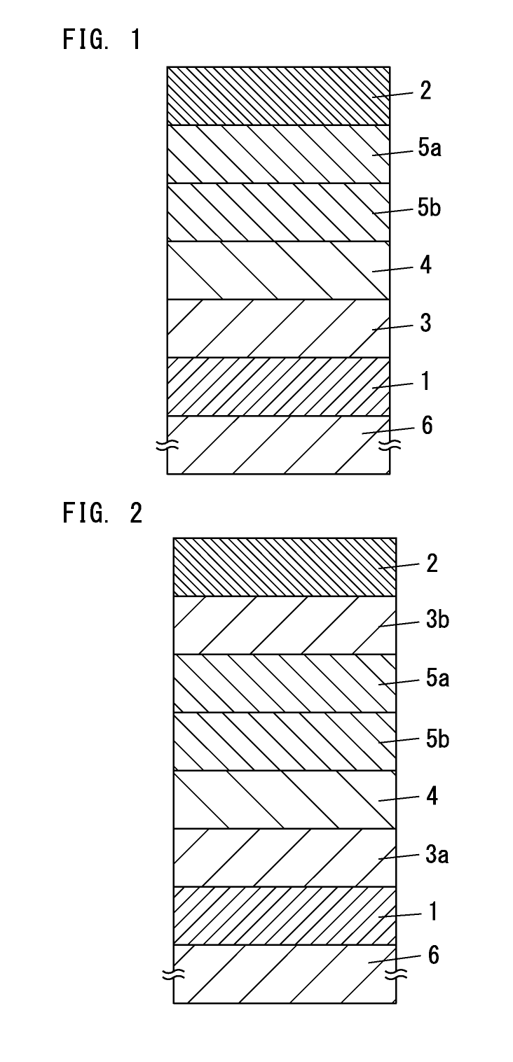

FIG. 2 shows another configuration instance of the present organic electroluminescence element. In this configuration instance, two light emitting layers 3a and 3b are interposed between anode 1 and cathode 2, and are separated from each other in the thickness direction. Further, the configuration instance includes first electron injection layer 5a and second electron injection layer 5b between light emitting layer 3a close to anode 1 and light emitting layer 3b close to cathode 2. First electron injection layer 5a and second electron injection layer 5b are arranged in this order from light emitting layer 3b close to cathode 2 to light emitting layer 3a close to anode 1. Besides, each of light emitting layers 3a and 3b may be made of a material suitable for forming light emitting layer 3 mentioned in the above.

According to the organic electroluminescence element having the configuration instance shown in FIG. 2, it is possible to improve the electron injection performance to light emitting layer 3a close to anode 1. Consequently, the light emitting efficiency can be improved and the driving voltage can be lowered. Besides, the configuration instance shown in FIG. 2 may be provided with a hole injection layer and/or a hole transport layer if necessary.

### Example 1

The organic electroluminescence element of the present example is based on the configuration shown in FIG. 1, and further includes, between anode 1 and light emitting layer 3, a laminated structure constituted by a hole injection layer (not shown) and a hole transport layer (not shown).

In the fabrication process of the organic electroluminescence element of the present example, substrate 6 on which an ITO film is formed as anode 1 was prepared. Substrate 6 was made of glass and had a thickness of 0.7 nm. The ITO film had a thickness of 150 nm, a square form of 5 mm by 5 mm, and a sheet resistance of about 10 Ω/sq. Substrate 6 was ultrasonically washed with a detergent for ten minutes, washed with ion-exchange water for ten minutes, and washed with acetone for ten minutes. Then, washed substrate 6 was vapor-washed with IPA (isopropylalcohol) and dried, and subsequently subjected to treatment using UV and O₃.

Next, substrate 6 was disposed within a chamber of a vacuum vapor deposition apparatus. Co-deposition of 4,4′-bis[N-(naphthyl)-N-phenyl-amino]biphenyl (alpha-NPD) and molybdenum oxide (MoO₃) at a molar ratio of 1:1 was performed under a decreased pressure of 1×10⁻⁴ Pa or less to form a co-deposited layer having a thickness of 30 nm on anode 1 as the hole injection layer. Then, an alpha-NPD layer having a thickness of 30 nm was deposited on the hole injection layer as the hole transport layer. Next, co-deposition of Alq₃ and quinacridone was performed (the weight percentage of quinacridone in Alq₃ is 3%) to form light emitting layer 3 having a thickness of 30 nm. Subsequently, a BCP layer having a thickness of 60 nm was deposited on light emitting layer 3 as electron transport layer 4. Thereafter, an IZO layer having a thickness of 40 nm was deposited on electron transport layer 4 as second electron injection layer 5b, and then a lithium layer having a thickness of 1 nm was deposited on second electron injection layer 5b as first electron injection layer 5a. Next, an aluminum layer having a thickness of 100 nm was deposited on first electron injection layer 5a as cathode 2. Besides, cathode 2 was formed at a deposition speed of 0.4 nm/s.

### Example 2

The organic electroluminescence element of the present example has the same basic configuration as that of the organic electroluminescence element of EXAMPLE 1, but is different from the organic electroluminescence element of EXAMPLE 1 in materials and thicknesses of second electron injection layer 5b and first electron injection layer 5a.

The fabrication process of the organic electroluminescence element of the present example was different from that of EXAMPLE 1 in only that an LiF layer having a thickness of 1 nm was formed on electron transport layer 4 on light emitting layer 3 as second electron injection layer 5b by use the resistive heating deposition and subsequently a cesium layer having a thickness of 1 nm was formed on second electron injection layer 5b as first electron injection layer 5a.

### Example 3

The organic electroluminescence element of the present example has the same basic configuration as that of the organic electroluminescence element of EXAMPLE 1, but is different from the organic electroluminescence element of EXAMPLE 1 in materials and thicknesses of second electron injection layer 5b and first electron injection layer 5a.

The fabrication process of the organic electroluminescence element of the present example was different from that of EXAMPLE 1 in only that an aluminum layer having a thickness of 2 nm was formed on electron transport layer 4 on light emitting layer 3 as second electron injection layer 5b by the resistive heating deposition and subsequently a potassium layer having a thickness of 3 nm was formed on second electron injection layer 5b as first electron injection layer 5a.

### Example 4

The organic electroluminescence element of the present example includes a hole transport layer (not shown) and a laminated structure, in addition to the configuration illustrated in FIG. 2. The hole transport layer is interposed between first electron injection layer 5a and light emitting layer 3b close to cathode 2. The laminated structure is constituted by an electron transport layer and an electron injection layer and is interposed between light emitting layer 3b and cathode 2.

In the fabrication process of the organic electroluminescence element of the present example, likewise EXAMPLE 1, substrate 6 on which an ITO film is formed as anode 1 was prepared. Substrate 6 was made of glass and had a thickness of 0.7 nm. The ITO film had a thickness of 150 nm, a square form of 5 mm by 5 mm, and a sheet resistance of about 10 Ω/sq. Substrate 6 was ultrasonically washed with a detergent for ten minutes, washed with ion-exchange water for ten minutes, and washed with acetone for ten minutes. Then, washed substrate 6 was vapor-washed with IPA (isopropylalcohol) and dried, and subsequently subjected to surface washing treatment using UV and O₃.

Next, substrate 6 was disposed within a chamber of a vacuum vapor deposition apparatus. Co-deposition of 4,4′-bis[N-(naphthyl)-N-phenyl-amino]biphenyl (alpha-NPD) and molybdenum oxide (MoO₃) at a molar ratio of 1:1 was performed under a decreased pressure of 1×10⁻⁴ Pa or less to form a co-deposited layer having a thickness of 30 nm on anode 1 as the hole injection layer. Then, an alpha-NPD layer having a thickness of 30 nm was deposited on the first hole injection layer as the hole transport layer (hereinafter referred to as “first hole transport layer”). Next, co-deposition of Alq₃ and quinacridone was performed (the weight percentage of quinacridone in Alq₃ is 3%) to form light emitting layer 3a (hereinafter referred to as “first light emitting layer 3a”) having a thickness of 30 nm. Subsequently, a BCP layer having a thickness of 60 nm was deposited on first light emitting layer 3a as electron transport layer 4. Thereafter, a molybdenum oxide layer having a thickness of 2 nm was deposited on electron transport layer 4a as second electron injection layer 5b, and then a rubidium layer having a thickness of 1 nm was deposited on second electron injection layer 5b as first electron injection layer 5a. Subsequently, an alpha-NPD layer having a thickness of 40 nm was deposited on first electron injection layer 5a as the hole transport layer (hereinafter referred to as “second hole transport layer”). Next, co-deposition of Alq₃ and quinacridone was performed (the weight percentage of quinacridone in Alq₃ is 7%) to form light emitting layer 3b (hereinafter referred to as “second light emitting layer 3b”) having a thickness of 30 nm. Thereafter, a BCP layer having a thickness of 40 nm was deposited on second light emitting layer 3b as the electron transport layer, and then a LiF layer having a thickness of 0.5 nm was deposited as the electron injection layer. Subsequently, an aluminum layer having a thickness of 100 nm was deposited as cathode 2. Besides, cathode 2 was formed at a deposition speed of 0.4 nm/s.

### Example 5

The organic electroluminescence element of the present example has the same basic configuration as that of the organic electroluminescence element of EXAMPLE 1, but is different from the organic electroluminescence element of EXAMPLE 1 in materials and thicknesses of second electron injection layer 5b and first electron injection layer 5a.

The fabrication process of the organic electroluminescence element of the present example was different from that of EXAMPLE 1 in only that an aluminum layer having a thickness of 2 nm was formed on electron transport layer 4 on light emitting layer 3 as second electron injection layer 5b by the resistive heating deposition and subsequently a lithium layer having a thickness of 1 nm was formed on second electron injection layer 5b as first electron injection layer 5a.

### Example 6

The organic electroluminescence element of the present example has the same basic configuration as that of the organic electroluminescence element of EXAMPLE 1, but is different from the organic electroluminescence element of EXAMPLE 1 in materials and thicknesses of second electron injection layer 5b and first electron injection layer 5a.

The fabrication process of the organic electroluminescence element of the present example was different from that of EXAMPLE 1 in only that a magnesium layer having a thickness of 2 nm was formed on electron transport layer 4 on light emitting layer 3 as second electron injection layer 5b by the resistive heating deposition and subsequently a lithium layer having a thickness of 1 nm was formed on second electron injection layer 5b as first electron injection layer 5a.

### Comparative Example 1

An organic electroluminescence element which is different from EXAMPLE 1 in that second electron injection layer 5b is not provided was prepared as COMPARATIVE EXAMPLE 1.

Measurement of a driving voltage and a light emitting efficiency of the respective organic electroluminescence elements of aforementioned EXAMPLE 1 and COMPARATIVE EXAMPLE was performed under a condition where an electrical current is supplied to a corresponding organic electroluminescence element at an electrical current density of 10 mA/cm². A result of this measurement is shown in below TABLE 1.

TABLE 1

| | driving voltage [V] | light emitting efficiency [%] |
|---|---|---|
| COMPARATIVE | 4.7 | 5.1 |
| EXAMPLE 1 | | |
| EXAMPLE 1 | 4.2 | 5.8 |

TABLE 1 shows that EXAMPLE 1 has the lower driving voltage and the higher light emitting efficiency than COMPARATIVE EXAMPLE.

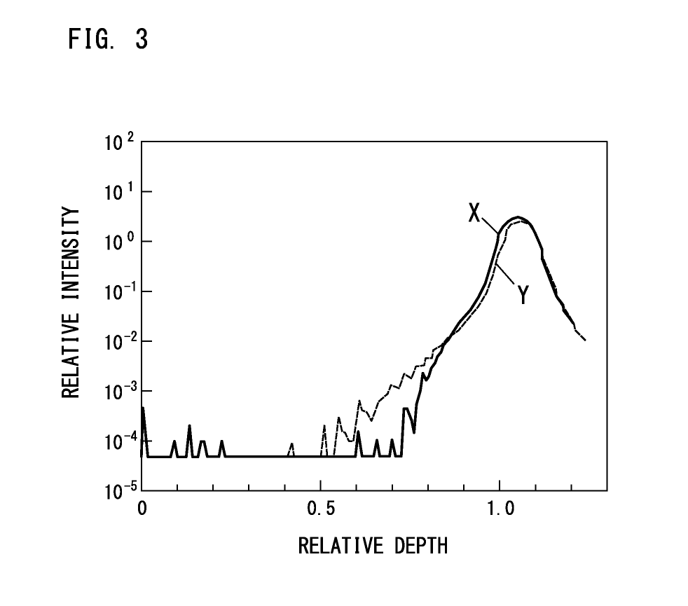

FIG. 3 shows depth profiles of Li with regard to the respective organic electroluminescence elements of EXAMPLE 1 and COMPARATIVE EXAMPLE 1 which were obtained by use of SIMS (Secondary Ion Mass Spectroscopy) analysis. In FIG. 3, a vertical axis denotes a relative intensity, and a horizontal axis denotes a relative depth (Normalized Position). The relative depth is defined by a distance to a position from the opposite surface of anode 1 to cathode 2 in a thickness direction. A position determined by the relative depth of 0 is corresponding to an interface between anode 1 and the hole injection layer. A position determined by the relative depth of 1.1 is corresponding to an interface between first electron injection layer 5a and cathode 2. With regard to FIG. 3, a solid line “X” represents a depth profile regarding EXAMPLE 1 and a broken line “Y” represents a depth profile regarding COMPARATIVE EXAMPLE 1. FIG. 3 shows that EXAMPLE 1 can suppress diffusion of Li toward the anode 1 in contrast to COMPARATIVE EXAMPLE 1.

As mentioned in the above, the organic electroluminescence element of EXAMPLE 1 can have the improved electron injection performance and further suppress the diffusion of alkali metal, in contrast to the organic electroluminescence element of COMPARATIVE EXAMPLE 1. Therefore, it is possible to improve the light emitting efficiency and lower the driving voltage.

1. An organic electroluminescence element comprising:
an anode;
a cathode;
a first electron injection layer made of an alkali metal and formed between said anode and said cathode;
an electron transport layer formed between said first electron injection layer and said anode; and
a light emitting layer formed between said electron transport layer and said anode,
wherein said organic electroluminescence element further comprises a second electron injection layer, said second electron injection layer being formed between said first electron injection layer and said electron transport layer, and
said second electron injection layer being made of an amorphous inorganic material.

2. An organic electroluminescence element as set forth in claim 1, wherein
said amorphous inorganic material is an electrically insulating inorganic material,
said second electron injection layer having an average thickness in a range of 0.3 nm to 30 nm.

3. An organic electroluminescence element as set forth in claim 2, wherein
said second electron injection layer has an average thickness in a range of 0.3 nm to 10 nm.

4. An organic electroluminescence element as set forth in claim 1, wherein
said amorphous inorganic material is an electrically insulating inorganic material with a specific electric resistance equal to or more than 1×105 Ωcm.

5. An organic electroluminescence element as set forth in claim 1, wherein
said amorphous inorganic material is an electrically conducting inorganic material with a specific electric resistance less than 1×105 Ωcm.

6. An organic electroluminescence element as set forth in claim 1, wherein
said alkali metal is lithium, and
said amorphous inorganic material is IZO.

7. An organic electroluminescence element as set forth in claim 1, wherein
said alkali metal is cesium, and
said amorphous inorganic material is LiF.

8. An organic electroluminescence element as set forth in claim 1, wherein
said alkali metal is lithium, and
said amorphous inorganic material is aluminum.

9. An organic electroluminescence element as set forth in claim 1, wherein
said alkali metal is rubidium, and
said amorphous inorganic material is molybdenum oxide.

10. An organic electroluminescence element as set forth in claim 1, wherein
said alkali metal is lithium, and
said amorphous inorganic material is magnesium.

11. An organic electroluminescence element as set forth in claim 5, wherein
said alkali metal is lithium, and
said amorphous inorganic material is IZO.

12. An organic electroluminescence element as set forth in claim 2, wherein
said alkali metal is cesium, and
said amorphous inorganic material is LiF.

13. An organic electroluminescence element as set forth in claim 3, wherein
said alkali metal is cesium, and
said amorphous inorganic material is LiF.

14. An organic electroluminescence element as set forth in claim 4, wherein
said alkali metal is cesium, and
said amorphous inorganic material is LiF.

15. An organic electroluminescence element as set forth in claim 5, wherein
said alkali metal is lithium, and
said amorphous inorganic material is aluminum.

16. An organic electroluminescence element as set forth in claim 2, wherein
said alkali metal is rubidium, and
said amorphous inorganic material is molybdenum oxide.

17. An organic electroluminescence element as set forth in claim 3, wherein
said alkali metal is rubidium, and
said amorphous inorganic material is molybdenum oxide.

18. An organic electroluminescence element as set forth in claim 4, wherein
said alkali metal is rubidium, and
said amorphous inorganic material is molybdenum oxide.

19. An organic electroluminescence element as set forth in claim 5, wherein
said alkali metal is lithium, and
said amorphous inorganic material is magnesium.
